(19) United States
(12) Patent Application Publication
(10) Pub. No.: US 2026/0220036 A1
(43) Pub. Date: Jul. 30, 2026

(54) EMI VALUE TESTING METHOD FOR LPDDR CHIP, AND SYSTEM, DEVICE, AND STORAGE MEDIUM THEREOF

(71) Applicant: Shenzhen Rayson Technology Co., Ltd., Shenzhen (CN)

(72) Inventor: Zi Liu, Shenzhen (CN)

(21) Appl. No.: 19/403,886

(22) Filed: Nov. 30, 2025

(30) Foreign Application Priority Data
Jan. 20, 2025 (CN) 2025100822752

(51) Int. Cl. G06F 12/02

(52) U.S. Cl. CPC G06F 12/023

(57) ABSTRACT

This disclosure discloses an EMI value testing method, a system, a device, and a storage medium for an LPDDR chip. The method comprises: obtaining a first storage capacity of the LPDDR chip; obtaining a second storage capacity of the LPDDR chip; comparing the first and second storage capacity with a preset storage capacity respectively to obtain a first comparison result; acquiring a first EMI value and a second EMI value based on the first comparison result, a first storage table, and a second storage table; and determining the EMI value of the LPDDR chip based on the first and second EMI values. By comprehensively and specifically detecting the storage capacity of two Ranks in the entire LPDDR chip and obtaining corresponding first and second EMI values based on the storage capacity, the EMI value of the LPDDR chip can be accurately tested.

### TECHNICAL FIELD

The disclosure relates to the technical field of memory testing, particularly to an EMI value testing method, a system, a device, and a storage medium for an LPDDR chip..

### BACKGROUND

LPDDR (Low-Power Double Data Rate SDRAM, a type of low-power double data rate random-access memory) is a memory device used in electronic equipment with stringent power consumption requirements, such as mobile devices and Internet of Things (IoT) devices. While meeting the equipment's demands for memory capacity and performance, it significantly reduces power consumption and extends the battery life of the devices.

Existing LPDDR chips are typically designed with a dual-channel architecture, meaning that one LPDDR chip comprises two channels (i.e., dual Ranks), with each channel (Rank) performing storage and access operations independently. Before initialization, an LPDDR chip needs to acquire an EMI (External Memory Interface) value to initialize itself based on this value. When testing the EMI value of an LPDDR chip using existing technologies, the test is usually conducted based on the total storage capacity of the LPDDR chip, and it can only test the EMI values corresponding to capacities below 12GB. Consequently, errors are prone to occur when testing the EMI values of different Ranks, leading to incorrect initialization configurations and thereby affecting the stability of the LPDDR chip.

### SUMMARY

In view of this, the objective of the embodiments of the present disclosure is to provide an EMI value testing method, a system, a device, and a storage medium for an LPDDR chip, which can accurately test the EMI value of the LPDDR chip, thereby accurately initializing the LPDDR chip and enhancing its stability.

In a first aspect, the embodiments of the present disclosure provide an EMI value testing method for an LPDDR chip, comprising:

obtaining a first storage capacity of the LPDDR chip, wherein the first storage capacity represents the storage capacity corresponding to a first Rank;

obtaining a second storage capacity of the LPDDR chip, wherein the second storage capacity represents the storage capacity corresponding to a second Rank;

comparing the first storage capacity and the second storage capacity with a preset storage capacity respectively to obtain a first comparison result;

ccquiring a first EMI value and a second EMI value based on the first comparison result, a first storage table, and a second storage table, wherein the first storage table represents a relationship table between a first parameter value and storage capacitystorage capacity, the second storage table represents a relationship table between a second parameter value and storage capacity, the first EMI value represents the EMI value of the first Rank, and the second EMI value represents the EMI value of the second Rank;

Determining the EMI value of the LPDDR chip based on the first EMI value and the second EMI value.

In some optional embodiments, the step of acquiring the first EMI value and the second EMI value based on the first comparison result, the first storage table, and the second storage table comprises:

when the first comparison result indicates that the first storage capacity is greater than the preset storage capacity, acquiring the first EMI value through the first storage table;

when the first comparison result indicates that the second storage capacity is greater than the preset storage capacity, acquiring the second EMI value through the first storage table;

when the first comparison result indicates that the first storage capacity is less than or equal to the preset storage capacity, acquiring the first EMI value through the second storage table;

when the first comparison result indicates that the second storage capacity is less than or equal to the preset storage capacity, acquiring the second EMI value through the second storage table.

In some optional embodiments, the method further comprises:

when the first comparison result indicates that both the first storage capacity and the second storage capacity are less than or equal to the preset storage capacity, comparing the first storage capacity and the second storage capacity to obtain a second comparison result;

when the second comparison result indicates that the first storage capacity and the second storage capacity are equal, acquiring the first EMI value and the second EMI value through the second storage table;

when the second comparison result indicates that the first storage capacity and the second storage capacity are not equal, acquiring the first EMI value and the second EMI value through the first storage table.

In some optional embodiments, the step of acquiring the first EMI value or the second EMI value through the first storage table, and acquiring the first EMI value or the second EMI value through the second storage table comprises:

acquiring a first parameter value from the first storage table based on the first storage capacity or the second storage capacity, and calculating the first EMI value or the second EMI value using the first parameter value;

acquiring a second parameter value from the second storage table based on the first storage capacity or the second storage capacity, and calculating the first EMI value or the second EMI value using the second parameter value.

In some optional embodiments, the step of determining the EMI value of the LPDDR chip based on the first EMI value and the second EMI value comprises:

acquiring a first weighting coefficient corresponding to the first EMI value and a second weighting coefficient corresponding to the second EMI value;

calculating the EMI value of the LPDDR chip based on the first EMI value, the first weighting coefficient, the second EMI value, and the second weighting coefficient.

In some optional embodiments, the step of acquiring the first parameter value from the first storage table based on the first storage capacity or the second storage capacity, and acquiring the second parameter value from the second storage table based on the first storage capacity or the second storage capacity comprises:

converting the first storage capacity or the second storage capacity to obtain a first table range of the first storage table;

configuring the parameter corresponding to the first table range as the first parameter value, wherein the first parameter value indicates the corresponding EMI value;

converting the first storage capacity or the second storage capacity to obtain a second table range of the second storage table;

configuring the parameter corresponding to the second table range as the second parameter value, wherein the second parameter value indicates the corresponding EMI value.

In some optional embodiments, prior to determining the EMI value of the LPDDR chip based on the first EMI value and the second EMI value, the method further comprises:

acquiring the operating mode of the LPDDR chip;

when the operating mode indicates a single-channel mode, setting the first EMI value corresponding to the inactive first Rank to zero, or setting the second EMI value corresponding to the inactive second Rank to zero;

when the operating mode indicates a dual-channel mode, acquiring an interference coefficient between the first Rank and the second Rank;

correcting the first EMI value and the second EMI value based on the interference coefficient.

In a second aspect, the embodiments of the present disclosure provide an EMI value testing system for an LPDDR chip, comprising:

a first module for obtaining a first storage capacity of the LPDDR chip, wherein the first storage capacity represents the storage capacity corresponding to the first Rank;

a second module for obtaining a second storage capacity of the LPDDR chip, wherein the second storage capacity represents the storage capacity corresponding to the second Rank;

a third module for comparing the first storage capacity and the second storage capacity with a preset storage capacity respectively to obtain a first comparison result;

a fourth module for acquiring a first EMI value and a second EMI value based on the first comparison result, the first storage table, and the second storage table, wherein the first storage table represents a relationship table between the first parameter value and storage capacity, the second storage table represents a relationship table between the second parameter values and storage capacity, the first EMI value represents the EMI value of the first Rank, and the second EMI value represents the EMI value of the second Rank;

a fifth module for determining the EMI value of the LPDDR chip based on the first EMI value and the second EMI value.

In a third aspect, the embodiments of the present disclosure provide a memory testing device applicable to a smart card, comprising:

at least one processor;

at least one memory for storing at least one program;

when the at least one program is executed by the at least one processor, the at least one processor implements the aforementioned method.

In a fourth aspect, the embodiments of the present disclosure provide a computer-readable storage medium storing a processor-executable program, which, when executed by a processor, is used to perform the aforementioned method.

Implementing the embodiments of the present disclosure comprises the following beneficial effects: The embodiments of the present disclosure provide an EMI value testing method for an LPDDR chip, comprising: obtaining a first storage capacity of the LPDDR chip, wherein the first storage capacity represents the storage capacity corresponding to the first Rank; obtaining a second storage capacity of the LPDDR chip, wherein the second storage capacity represents the storage capacity corresponding to the second Rank; comparing the first storage capacity and the second storage capacity with a preset storage capacity respectively to obtain a first comparison result; acquiring a first EMI value and a second EMI value based on the first comparison result, the first storage table, and the second storage table, wherein the first storage table represents a relationship table between first parameter values and storage capacities, the second storage table represents a relationship table between second parameter values and storage capacities, the first EMI value represents the EMI value of the first Rank, and the second EMI value represents the EMI value of the second Rank; determining the EMI value of the LPDDR chip based on the first EMI value and the second EMI value. This application can effectively compensate for the deficiencies of existing testing methods by comprehensively and specifically detecting the storage capacities of the two Ranks in the entire LPDDR chip and acquiring corresponding first and second EMI values based on the storage capacities, thereby accurately testing the EMI value of the LPDDR chip, accurately initializing the LPDDR chip, and enhancing its stability. Additionally, by detecting the storage capacities of the first Rank and the second Rank separately and acquiring corresponding EMI values, EMI value testing can be performed on LPDDR chips with capacities exceeding 12GB.

### BRIEF DESCRIPTION OF THE DRAWINGS

FIG. 1 is a schematic step - flow diagram of an EMI value testing method for an LPDDR chip provided in an embodiment of the present disclosure;

FIG. 2 is a schematic diagram of the first Rank and the second Rank of an LPDDR chip provided in an embodiment of the present disclosure;

FIG. 3 is a structural block diagram of an EMI value testing system for an LPDDR chip provided in an embodiment of the present disclosure;

FIG. 4 is a structural block diagram of a memory testing device provided in an embodiment of the present disclosure.

### DETAILED DESCRIPTION

To make the objectives, technical solutions, and advantages of the present disclosure clearer, the following provides a further detailed description of the present disclosure in conjunction with the accompanying drawings and embodiments. It should be understood that the specific embodiments described here are only used to explain the present disclosure and are not intended to limit it.

It should be noted that although functional modules are divided in the device schematic diagrams and logical sequences are shown in the flowcharts, in some cases, the steps illustrated or described may be executed in a sequence different from the module division in the device or the sequence in the flowchart. The terms "first," "second," etc. in the specification, claims, or the above-mentioned drawings are used to distinguish similar objects and are not necessarily used to describe a specific order or sequence.

An embodiment of the present disclosure provides an EMI value testing method for an LPDDR chip, which comprises the following steps: obtaining the first storage capacity of the LPDDR chip, wherein the first storage capacity represents the storage capacity corresponding to the first Rank; obtaining the second storage capacity of the LPDDR chip, wherein the second storage capacity represents the storage capacity corresponding to the second Rank; comparing the first storage capacity and the second storage capacity respectively with a preset storage capacity to obtain a first comparison result; obtaining a first EMI value and a second EMI value based on the first comparison result, a first storage table, and a second storage table, wherein the first storage table represents a relationship table between the first parameter value and storage capacity, the second storage table represents a relationship table between the second parameter value and storage capacity, the first EMI value represents the EMI value of the first Rank, and the second EMI value represents the EMI value of the second Rank; and determining the EMI value of the LPDDR chip based on the first EMI value and the second EMI value. This application can effectively make up for the deficiencies of existing testing methods. By comprehensively and specifically detecting the storage capacities of the two Ranks in the entire LPDDR chip and obtaining corresponding first and second EMI values based on the storage capacities, it can accurately test the EMI value of the LPDDR chip, thereby accurately initializing the LPDDR chip and improving its stability. Meanwhile, by detecting the storage capacities of the first Rank and the second Rank separately and then obtaining the corresponding EMI values, it enables EMI value testing for LPDDR chips with a capacity of over 12GB.

The following elaborates further on the embodiments of the present disclosure with reference to the accompanying drawings.

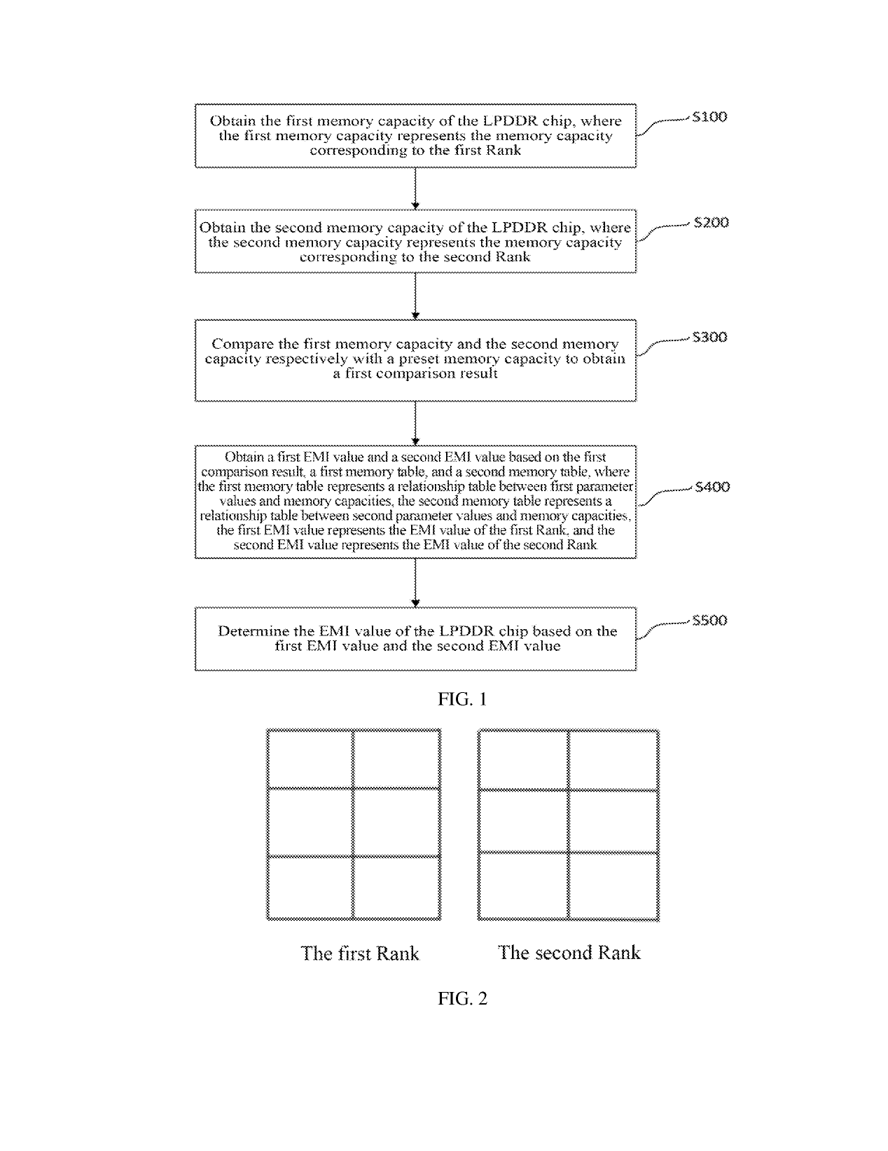

As shown in FIG. 1, an embodiment of the present disclosure provides an EMI value testing method for an LPDDR chip, which comprises the following steps:

S100: obtaining the first memory capacity of the LPDDR chip, wherein the first memory capacity represents the memory capacity corresponding to the first Rank;

S200: obtaining the second memory capacity of the LPDDR chip, wherein the second memory capacity represents the memory capacity corresponding to the second Rank;

S300: compare the first memory capacity and the second memory capacity respectively with a preset memory capacity to obtain a first comparison result;

S400: obtaining a first EMI value and a second EMI value based on the first comparison result, a first memory table, and a second memory table, wherein the first memory table represents a relationship table between first parameter values and memory capacities, the second memory table represents a relationship table between second parameter values and memory capacities, the first EMI value represents the EMI value of the first Rank, and the second EMI value represents the EMI value of the second Rank;

S500: determining the EMI value of the LPDDR chip based on the first EMI value and the second EMI value.

Specifically, referring to FIG. 2, first, it is necessary to obtain the first memory capacity corresponding to the first Rank and the second memory capacity corresponding to the second Rank in the LPDDR chip. The acquisition of memory capacities can be achieved through registers within the chip or specific read instructions, and the specific method is not limited herein. The first memory capacity and the second memory capacity are respectively compared with a preset memory capacity. This preset memory capacity is a pre-determined value, set according to system design or experience. In this application, the specific preset memory capacity is 6GB. The first EMI value and the second EMI value are obtained using the first memory table and the second memory table. The first memory table records the relationship between first parameter values and memory capacities; if the first memory capacity falls within a certain range after comparison with the preset memory capacity, the corresponding first parameter value can be found in the first memory table based on this range, thereby obtaining the first EMI value. The same principle applies to the second memory table; based on the comparison result between the second memory capacity and the preset memory capacity, the corresponding second parameter value can be found in the second memory table, thereby obtaining the second EMI value. The combined memory capacity of the first memory capacity and the second memory capacity can obviously be greater than 12GB. Compared to testing the entire LPDDR chip, this method allows for independent testing of the EMI values of different Ranks without being limited by the overall memory capacity of the LPDDR chip. Moreover, when testing the entire LPDDR chip, if the memory capacity of the LPDDR chip is evenly distributed to the first Rank and the second Rank, and the memory capacities of the first Rank and the second Rank themselves are unequal, the obtained EMI values will obviously have deviations, leading to initialization errors of the LPDDR chip and subsequently affecting its performance during subsequent use, resulting in poor stability of the LPDDR chip. The EMI value of the entire LPDDR chip is determined based on the obtained first EMI value and second EMI value, thereby initializing the LPDDR chip according to its EMI value. Since it integrates the first EMI value and the second EMI value, the initialization is accurate.

In some optional embodiments, the step of obtaining the first EMI value and the second EMI value based on the first comparison result, the first memory table, and the second memory table comprises: obtaining the first EMI value through the first memory table when the first comparison result indicates that the first memory capacity is greater than the preset memory capacity; obtaining the second EMI value through the first memory table when the first comparison result indicates that the second memory capacity is greater than the preset memory capacity; obtaining the first EMI value through the second memory table when the first comparison result indicates that the first memory capacity is less than or equal to the preset memory capacity; obtaining the second EMI value through the second memory table when the first comparison result indicates that the second memory capacity is less than or equal to the preset memory capacity.

Specifically, based on the different results obtained by comparing the memory capacities of each Rank (in this case, the first Rank and the second Rank) in the LPDDR chip with the preset memory capacity (6GB is selected in this application), the corresponding EMI values are precisely searched for and obtained from the corresponding memory tables (the first memory table and the second memory table). Appropriate External Memory Interface (EMI) parameters are determined for Ranks with different memory capacities to initialize the LPDDR chip, ensuring that the LPDDR chip can operate stably with good electromagnetic compatibility and data transmission performance in the entire electronic system. When the first comparison result shows that the first memory capacity is greater than the preset memory capacity, it means that the actual storage capacity of the first Rank exceeds the expected setting. In this case, the chip has relatively high data storage and transmission requirements, and an EMI value that matches this large capacity is needed to meet the efficient data read/write operations and maintain a reasonable electromagnetic environment. The first memory table records the mapping relationship between memory capacity and EMI values under specific conditions. In this scenario where the capacity is greater than the preset value, by looking up the first parameter corresponding to the first memory capacity in the first memory table, the corresponding first EMI value can be obtained. For example, when the first memory capacity is 8GB, the corresponding first EMI value comprises specific parameters such as a clock frequency set to 1800 MHz, a data bit width of 32 bits, and a read/write delay of 8 ns. These parameters combined form the EMI value required by the first Rank to ensure its efficiency and stability during large-capacity data operations.

Similar to the situation of the first Rank, when the second memory capacity is greater than the preset memory capacity, it indicates that the second Rank also has a relatively high storage capacity and similar changes in data transmission and electromagnetic characteristics requirements. The second EMI value is again obtained using the first memory table, which is stored in the CONK register. The first memory table is constructed for situations with relatively large memory capacities and covers the corresponding relationships between EMI values required for efficient data exchange in large-capacity Ranks.Therefore, by looking up the corresponding record in the first memory table according to the second memory capacity, the second EMI value suitable for the second Rank in a large-capacity state can be determined, ensuring its good collaboration with other components in the system and achieving stable data read/write operations.

When the first memory capacity is less than or equal to the preset memory capacity (6GB), it means that the storage scale of the first Rank is relatively small or exactly meets the expectation. In this case, its data storage and transmission requirements are relatively lower, and the corresponding EMI value should be adapted to these relatively low data processing requirements and maintain appropriate electromagnetic characteristics. The second memory table is formulated for situations where the memory capacity is in a relatively small range and records the corresponding relationships between memory capacity and EMI values under such capacity conditions. Therefore, by looking up the second parameter in the second memory table that matches the first memory capacity, the first EMI value suitable for the current situation of the first Rank can be obtained. For example, if the first memory capacity is 4GB (with the preset memory capacity being 6GB), the EMI value corresponding to 4GB can be found in the second memory table, such as parameters including a clock frequency of 1200 MHz, a data bit width of 16 bits, and a read/write delay of 12 ns. These parameters can ensure that the first Rank can exchange data stably and efficiently at the corresponding capacity.

When the second memory capacity is less than or equal to the preset memory capacity, the same approach as that for the first Rank in the same situation is adopted. Since its storage capacity is at a relatively low level, the EMI value needs to be determined according to the configuration rules for corresponding smaller capacities. By using the second memory table and looking up the corresponding record in the table based on the specific value of the second memory capacity, the second EMI value suitable for the second Rank in this small-capacity situation can be obtained, enabling the second Rank to achieve the best state in terms of data read/write operations and electromagnetic compatibility according to its capacity characteristics, and ensuring the stable operation of the entire LPDDR chip in the system.

In some optional embodiments, the method further comprises: comparing the first memory capacity and the second memory capacity to obtain a second comparison result when the first comparison result indicates that both the first memory capacity and the second memory capacity are less than or equal to the preset memory capacity; obtaining the first EMI value and the second EMI value through the second memory table when the second comparison result indicates that the first memory capacity and the second memory capacity are equal ;obtaining the first EMI value and the second EMI value through the first memory table when the second comparison result indicates that the first memory capacity and the second memory capacity are not equal.

Specifically, on the basis of having initially determined from which memory table to obtain the corresponding EMI values based on the comparison results between the memory capacities of each Rank and the preset memory capacity, here we further consider the impact of the relationship between the first memory capacity and the second memory capacity on obtaining EMI values in the specific case where both are less than or equal to the preset memory capacity. This is aimed at more precisely adapting the corresponding EMI values according to the specific situations of Rank capacities, so that the LPDDR chip can achieve good electromagnetic compatibility and data transmission performance under different memory capacity configurations, ensuring the stable operation of the entire electronic system.

When the first comparison result shows that both the first memory capacity and the second memory capacity are less than or equal to the preset memory capacity, it means that the storage scales of these two Ranks are at a relatively low level. However, relying solely on this is not sufficient to fully determine the most appropriate way to obtain EMI values. Because even within the relatively small capacity range, the situations where the two Rank capacities are equal and not equal have different impacts on data transmission and electromagnetic characteristics. Therefore, it is necessary to further compare their capacities to obtain a second comparison result, which can be used to more precisely determine from which memory table to obtain EMI values.

When the second comparison result indicates that the first memory capacity and the second memory capacity are equal, it means that the two Ranks have the same storage capacity. In this case, their data storage and transmission requirements are consistent from the perspective of capacity, and the adapted EMI values should also be the same. Since it has been previously determined that both Rank capacities are less than or equal to the preset memory capacity, and the second memory table is constructed for relatively small memory capacity situations, recording the corresponding relationships between memory capacity and EMI values under such capacity conditions. Given that the two Rank capacities are equal and within the small capacity range, we can directly look up the second parameter corresponding to this capacity in the second memory table, and then obtain the first EMI value suitable for the first Rank and the second EMI value suitable for the second Rank. This ensures that the two Ranks can perform stable data interaction with appropriate electromagnetic characteristics and data transmission parameters under the equal and small capacity configuration.

When the second comparison result indicates that the first memory capacity and the second memory capacity are not equal, although they are both within the relatively small capacity range, different capacities imply differences in the specific data storage and transmission requirements of the two Ranks. For example, a Rank with a larger capacity may relatively require a slightly higher data transmission bandwidth. This necessitates comprehensive consideration to determine the appropriate EMI values. Although it was previously mentioned that the first memory table is mainly constructed for relatively large memory capacity situations, here, when the two Rank capacities are not equal and both are within the relatively small capacity range, obtaining EMI values through the first memory table is because the capacity range covered by the first memory table and its corresponding EMI value mapping relationships can better adapt to this complex situation with capacity differences. Based on the specific capacity values of the two Ranks, it can look up the corresponding first parameters in the table, and then obtain the first EMI value and the second EMI value respectively suitable for the first Rank and the second Rank. This enables the two Ranks with different capacities to optimize data transmission performance and maintain good electromagnetic compatibility as much as possible under this relatively small capacity configuration, ensuring the stable operation of the entire LPDDR chip in the system.

In some optional embodiments, obtaining the first EMI value or the second EMI value through the first memory table and obtaining the first EMI value or the second EMI value through the second memory table comprise: obtaining the first parameter value from the first memory table according to the first memory capacity or the second memory capacity, and calculating the first EMI value or the second EMI value through the first parameter value; obtaining the second parameter value from the second memory table according to the first memory capacity or the second memory capacity, and calculating the first EMI value or the second EMI value through the second parameter value.

Specifically, the first memory table establishes a mapping relationship between memory capacity and the first parameter value. When it is necessary to obtain the first EMI value or the second EMI value through the first memory table, the first step is to look up the corresponding first parameter value based on the specific first memory capacity or second memory capacity. For example, the first memory table lists corresponding parameter combinations according to different memory capacity ranges. If the first memory capacity is 8GB (just an example value), the record corresponding to 8GB is looked up in the table. The parameters related to capacity (i.e., the first parameter value) included in this record cover aspects such as the specific chip operating mode code and coefficients related to data transmission bandwidth. These parameters serve as the basis for subsequent EMI value calculations.

After obtaining the first parameter value, a specific calculation method is required to derive the first EMI value or the second EMI value. These first parameter values are closely related to the chip's electromagnetic characteristics and data transmission mechanism, and the calculation process is often based on some mathematical models or algorithms determined during chip design. For instance, the chip operating mode code in the first parameter value determines the basic data transmission mode (such as single-channel or dual-channel). Different modes correspond to different basic parameter settings such as clock frequency and data bit width. The coefficient related to data transmission bandwidth participates in the calculation of key EMI parameters such as the actual data transmission speed. By substituting these first parameter values into corresponding calculation formulas (the specific formulas are determined by the chip manufacturer based on factors such as the chip's electrical characteristics and performance goals, and are not limited here), and through mathematical operations such as multiplication, addition, and bit shifting, the first EMI value or the second EMI value is finally obtained. This accurately configures the external memory interface parameters of the corresponding Rank, meets its data transmission requirements at this capacity, and controls the level of electromagnetic interference.

Similar to the first memory table, the second memory table also constructs a corresponding relationship between memory capacity and the second parameter value. When it is necessary to obtain the first EMI value or the second EMI value through the second memory table, the corresponding entry is looked up in the second memory table according to the involved first memory capacity or second memory capacity to determine the second parameter value. For example, if the second memory capacity is 4GB, the set of parameters corresponding to 4GB is looked up in the second memory table. The second parameter value covers parameters related to the chip's internal memory structure, such as the number of memory banks and the number of row and column addresses, as well as other relevant coefficients that affect electromagnetic characteristics. These reflect the key characteristic information of the chip under relatively small memory capacity conditions. After obtaining the second parameter value, the first EMI value or the second EMI value is calculated according to established calculation rules. Since the second parameter value reflects the characteristics of the chip under relatively small capacity scenarios, the method of calculating the EMI value is centered around optimizing data transmission and electromagnetic compatibility within this capacity range. For example, the number of memory banks and the number of row and column addresses in the second parameter value affect the data read/write method and access efficiency. Through a specific algorithm (which takes into account the relationship between these parameters and electromagnetic interference and data transmission speed) and combined with other relevant coefficients, mathematical operations are performed to finally calculate the first EMI value or the second EMI value suitable for the corresponding Rank under this relatively small capacity condition, enabling the chip to operate stably with reasonable electromagnetic characteristics and data transmission performance under a relatively low capacity configuration.

In some optional embodiments, determining the EMI value of the LPDDR chip based on the first EMI value and the second EMI value comprises: obtaining a first weighting coefficient corresponding to the first EMI value and a second weighting coefficient corresponding to the second EMI value; calculating the EMI value of the LPDDR chip according to the first EMI value, the first weighting coefficient, the second EMI value, and the second weighting coefficient.

Specifically, after the first EMI value and the second EMI value have been obtained, in order to comprehensively consider the respective electromagnetic characteristics of the two Ranks (the first Rank and the second Rank) and their impacts on the electromagnetic compatibility and data transmission performance of the entire LPDDR chip, the EMI value of the entire LPDDR chip is determined by obtaining the corresponding weighting coefficients and using these coefficients for calculation. This approach more scientifically and accurately reflects the overall electromagnetic performance of the chip, ensuring that when the chip works in coordination with external systems, it can achieve good data transmission efficiency and meet the required electromagnetic compatibility while taking into account the conditions of each Rank, thereby safeguarding the stable operation of the entire electronic system.

The first weighting coefficient corresponds to the first EMI value, and the second weighting coefficient corresponds to the second EMI value. They respectively reflect the relative importance or influence of the first Rank and the second Rank within the entire LPDDR chip. This relative importance is determined by multiple factors, such as the memory capacity of the Rank, the frequency of data read and write operations, and the position within the overall chip data storage and transmission system.

If the memory capacity of the first Rank is relatively large and it occupies a more dominant position in the entire chip storage system, undertaking more data storage tasks, then its corresponding first weighting coefficient may be relatively large, indicating that it has a stronger influence in determining the EMI value of the entire chip. For example, if the first Rank has a capacity of 8GB and the second Rank has a capacity of 4GB, considering the capacity factor, the first weighting coefficient of the first Rank will be set higher than the second weighting coefficient of the second Rank because the Rank with a larger capacity has a relatively greater impact on electromagnetic characteristics in aspects such as data transmission. Suppose the first Rank is mainly used to store core operating system files and frequently accessed application data, with very frequent data read and write operations, while the second Rank is mainly used to store relatively less frequently accessed backup data, etc. Then, due to its high read and write frequency, the first Rank has a more critical impact on the overall data transmission performance and electromagnetic environment of the chip. Accordingly, the first weighting coefficient will be larger to reflect its importance in determining the chip's EMI value.

The process of calculating the EMI value of the LPDDR chip is based on the idea of weighted averaging, that is, multiplying the first EMI value and the second EMI value by their corresponding weighting coefficients respectively and then summing them up to obtain the final chip EMI value. This approach can comprehensively consider the respective electromagnetic characteristics of the two Ranks and their importance within the chip, making the obtained chip EMI value more in line with actual working conditions.

In some optional embodiments, obtaining the first parameter value from the first memory table according to the first memory capacity or the second memory capacity, and obtaining the second parameter value from the second memory table according to the first memory capacity or the second memory capacity comprise: converting the first memory capacity or the second memory capacity to obtain a first table range of the first memory table; configuring the parameters corresponding to the first table range as the first parameter value, wherein the first parameter value indicates the corresponding EMI value; converting the first memory capacity or the second memory capacity to obtain a second table range of the second memory table; configuring the parameters corresponding to the second table range as the second parameter value, wherein the second parameter value indicates the corresponding EMI value.

Specifically, the first memory table divides different memory capacity ranges according to certain rules and configures corresponding parameter combinations (i.e., the first parameter values) for each range. When the first memory capacity or the second memory capacity is known, it is necessary to determine the first table range to which it belongs based on the pre-set capacity division logic of the memory table. For example, the first memory table may divide the memory capacity into several intervals, such as 0 - 4GB as one interval and 4GB - 8GB as another interval. Each interval corresponds to different parameter combinations related to the chip's operating mode, data transmission bandwidth, etc. If the first memory capacity is 6GB, according to this division rule, it can be determined that its first table range is the 4GB - 8GB interval. For a dual-channel LPDDR chip, when dividing the table ranges of the first memory table, the capacity of each Rank and the number of channels are considered simultaneously. For instance, when there are two Ranks and each Rank has a capacity in the range of 3GB - 6GB, it corresponds to a specific table range. This is because chips with such a capacity combination in dual-channel mode have unique performances in terms of electromagnetic characteristics and data transmission, requiring special parameter configurations for adaptation.

After determining the first table range corresponding to the first memory capacity or the second memory capacity, the pre-configured parameter combination for this range can be set as the first parameter value. These first parameter values are closely related to the chip's electromagnetic characteristics and data transmission mechanism and directly indicate the corresponding EMI values. For example, in a certain first table range (assuming it is the memory capacity interval of 8GB - 12GB), the first parameter value may comprise parameters such as a clock frequency set to 1800 MHz, a data bit width of 32 bits, a read-write delay of 8 ns, and a specific address mapping method. These parameter combinations represent the external memory interface (EMI) configuration required by the chip in this capacity interval to achieve good electromagnetic compatibility and efficient data transmission, that is, corresponding to a specific EMI value. Subsequently, these parameters can be further calculated or directly applied to set the chip's EMI-related configurations. The various parameters covered by the first parameter value are mutually collaborative and influential. For example, the clock frequency and data bit width jointly determine the data transmission speed, and the read-write delay needs to be adapted to them to ensure the accuracy and stability of data during the read-write process. At the same time, the address mapping method also affects data access efficiency and electromagnetic interference. Therefore, as an overall first parameter value, these parameters comprehensively reflect the electromagnetic characteristics and data transmission-related configuration information required by the chip within the corresponding table range.

Similar to looking up the corresponding table range in the first memory table, the second memory table also has its own capacity range division method to match different second parameter values. According to the first memory capacity or the second memory capacity, it is converted to the corresponding second table range based on the established capacity division rules of the second memory table. For example, the second memory table may be divided according to a finer capacity gradient, such as 0 - 2GB as one interval and 2GB - 4GB as another interval. If the second memory capacity is 3GB, its corresponding second table range is the 2GB - 4GB interval, thus finding the range suitable for parameter configuration under relatively small capacity conditions. The capacity division and determination of table ranges in the second memory table often focus on relatively small memory capacity situations and are different from those in the first memory table. It takes more into account the particularities of the chip's internal memory structure, data read-write characteristics, and electromagnetic characteristics under low-capacity conditions. For example, at low capacities, more attention may be paid to reducing power consumption and optimizing electromagnetic compatibility in simple data access modes. Therefore, the division of table ranges and corresponding parameter configurations are designed around these characteristics, complementing the first memory table for larger capacity situations to comprehensively cover the chip's needs in different capacity scenarios.

After determining the second table range corresponding to the second memory capacity, the parameter combination corresponding to this range is set as the second parameter value, and its principle and function are similar to those of the first parameter value. These second parameter values also indicate the corresponding EMI values, but they are for configurations under relatively small capacity conditions. For example, in the second table range (assuming it is the memory capacity interval of 2GB - 4GB), the second parameter value may comprise parameters such as a clock frequency set to 1200 MHz, a data bit width of 16 bits, a read-write delay of 12 ns, and an address mapping method suitable for low capacities. These parameters together constitute the parameters related to the chip's optimal EMI configuration in this capacity interval, providing a guarantee for stable and efficient data transmission of the chip under relatively low-capacity conditions. By comparing the first parameter value and the second parameter value, it can be found that since they correspond to different memory capacity ranges, the parameter values show significant differences to adapt to the characteristics of the chip in their respective capacity situations. Generally, the parameters such as clock frequency and data bit width corresponding to the second parameter value are relatively small, and the read-write delay is relatively long. This is because under low-capacity conditions, the data transmission demand is relatively low, and more emphasis is placed on maintaining low power consumption and a simple and stable electromagnetic environment. On the other hand, the first parameter value sets parameters such as a relatively higher clock frequency and a wider data bit width according to the needs for high-speed data transmission and large-capacity data processing at larger capacities to meet its performance requirements.

In some optional embodiments, before determining the EMI value of the LPDDR chip according to the first EMI value and the second EMI value, the method further comprises: obtaining the operating mode of the LPDDR chip; setting the first EMI value corresponding to the non-operating first Rank to zero or setting the second EMI value corresponding to the non-operating second Rank to zero when the operating mode indicates a single-channel mode;obtaining the interference coefficient between the first Rank and the second Rank when the operating mode indicates a dual-channel mode; and correcting the first EMI value and the second EMI value according to the interference coefficient.

Specifically, before finally determining the overall EMI value of the LPDDR chip based on the first EMI value and the second EMI value, it is necessary to consider the chip's operating mode and the mutual influence between different Ranks under different operating modes. The aim is to more precisely adjust the EMI values corresponding to each Rank so that they fully reflect the electromagnetic characteristics and data transmission conditions of the chip in actual operating states, thereby obtaining an overall chip EMI value that is more in line with reality and can ensure the stable and efficient operation of the chip, and improving the electromagnetic compatibility and performance of the chip when working in collaboration with external systems.

The operating mode of the LPDDR chip (single-channel mode or dual-channel mode) has a significant impact on its data transmission method, electromagnetic interference situation, and overall performance. Different operating modes mean differences in the data interaction mechanism between the chip's internal memory cells and the external system. Correspondingly, the roles played by each Rank and the relationships between them will also be different. Therefore, it is first necessary to clarify the current operating mode of the chip so as to make targeted adjustments to the EMI values later. Usually, the operating mode can be determined by reading specific register bits inside the chip or detecting relevant control signals connected to the chip. For example, the chip can reserve one or several register bits specifically for indicating whether it is in single-channel or dual-channel operating mode. An external memory controller can obtain the chip's operating mode information by accessing these registers and parsing the binary values therein (e.g., 0 represents single-channel mode and 1 represents dual-channel mode); or the operating mode can be judged by detecting the voltage level state of specific pins used for controlling channel selection, providing a basis for further processing the EMI values of each Rank later.

In single-channel mode, only one Rank participates in operations such as data reading and writing, while the other Rank is in a non-operating state. The Rank in the non-operating state actually does not have a substantive impact on the current data transmission and electromagnetic environment. Therefore, from the perspective of accurately reflecting the chip's actual electromagnetic characteristics and data transmission conditions, it is necessary to set the EMI value corresponding to the non-operating Rank to zero. For example, if it is currently in single-channel mode and the first Rank is not operating, then the first EMI value corresponding to the first Rank is set to zero. This first EMI value was originally a comprehensive value obtained based on factors such as the storage capacity of the first Rank, including a series of parameters related to electromagnetic characteristics such as clock frequency and data bit width. Setting it to zero means that in the subsequent calculation process of determining the overall chip EMI value, the non-operating first Rank will not contribute to the final result, just as if it did not exist. This ensures that the calculated chip EMI value can accurately reflect the electromagnetic situation of the Rank actually participating in the work in single-channel mode. Similarly, if the second Rank is not operating, the corresponding second EMI value is set to zero, making the overall EMI value calculation more in line with the actual working scenario.

In dual-channel mode, the first Rank and the second Rank operate simultaneously for data reading and writing operations. However, when the two Ranks operate simultaneously, due to reasons such as their sharing of some internal chip resources (e.g., address buses and data buses) and their physical proximity, they may generate electromagnetic interference with each other. This interference can affect the accuracy and stability of data transmission and thus change the overall electromagnetic characteristics of the chip. Therefore, it is necessary to obtain the interference coefficient between them to quantify the degree of this interference influence so as to reasonably correct the EMI values corresponding to each Rank.

The interference coefficient is usually obtained through a large number of experimental tests and electromagnetic compatibility (EMC) modeling analysis during the chip design stage. During the chip R&D process, professional electromagnetic interference detection equipment is used to test the two Ranks operating simultaneously in dual-channel mode under different working conditions and data transmission scenarios. Relevant indicators such as the data transmission error rate and electromagnetic radiation changes caused by mutual interference are measured, and then these indicators are quantified into an interference coefficient through a specific algorithm (this algorithm comprehensively considers the influence relationship between interference and each EMI parameter). For example, the interference coefficient can be a numerical value between 0 and 1, with a larger value indicating more severe interference. It reflects the degree to which the mutual interference between the first Rank and the second Rank affects their respective electromagnetic characteristics and data transmission performance.

After obtaining the interference coefficient, the first EMI value and the second EMI value are corrected according to its numerical value. The specific correction method can be based on a correction algorithm determined during chip design, which takes into account the relationship between the interference coefficient and each EMI parameter (such as clock frequency, data bit width, read-write delay, etc.). For example, if the interference coefficient is large, indicating strong interference between the Ranks, it may be necessary to appropriately reduce the clock frequency, adjust the data bit width, or increase the read-write delay and other EMI parameter values to offset the impact of interference on data transmission and ensure the stability and electromagnetic compatibility of data transmission in dual-channel mode. Taking the clock frequency as an example, assume that the original clock frequency in the first EMI value is 1600 MHz. According to the interference coefficient (assume it is 0.6, indicating relatively severe interference) and the corresponding correction algorithm, the clock frequency in the first EMI value is corrected to 1200 MHz. The second EMI value is also corrected accordingly in a similar logic, so that the corrected first EMI value and second EMI value can better adapt to the actual working situation with interference in dual-channel mode, laying a foundation for finally accurately determining the overall EMI value of the LPDDR chip.

Implementing the embodiments of the present disclosure offers the following beneficial effects. The embodiments of the present disclosure provide an EMI value testing method for an LPDDR chip, which comprises: obtaining the first storage capacity of the LPDDR chip, wherein the first storage capacity represents the storage capacity corresponding to the first Rank; obtaining the second storage capacity of the LPDDR chip, wherein the second storage capacity represents the storage capacity corresponding to the second Rank; comparing the first storage capacity and the second storage capacity with a preset storage capacity respectively to obtain a first comparison result; obtaining a first EMI value and a second EMI value based on the first comparison result, a first storage table, and a second storage table, wherein the first storage table represents a relationship table between first parameter values and storage capacities, the second storage table represents a relationship table between second parameter values and storage capacities, the first EMI value represents the EMI value of the first Rank, and the second EMI value represents the EMI value of the second Rank; and determining the EMI value of the LPDDR chip based on the first EMI value and the second EMI value. This application can effectively compensate for the deficiencies of existing testing methods. By comprehensively and specifically detecting the storage capacities of the two Ranks in the entire LPDDR chip and obtaining corresponding first and second EMI values based on the storage capacities, it can accurately test the EMI value of the LPDDR chip, thereby accurately initializing the LPDDR chip and improving its stability. Meanwhile, by detecting the storage capacities of the first Rank and the second Rank separately and then obtaining corresponding EMI values, it can test the EMI value of LPDDR chips with a capacity of over 12 GB.

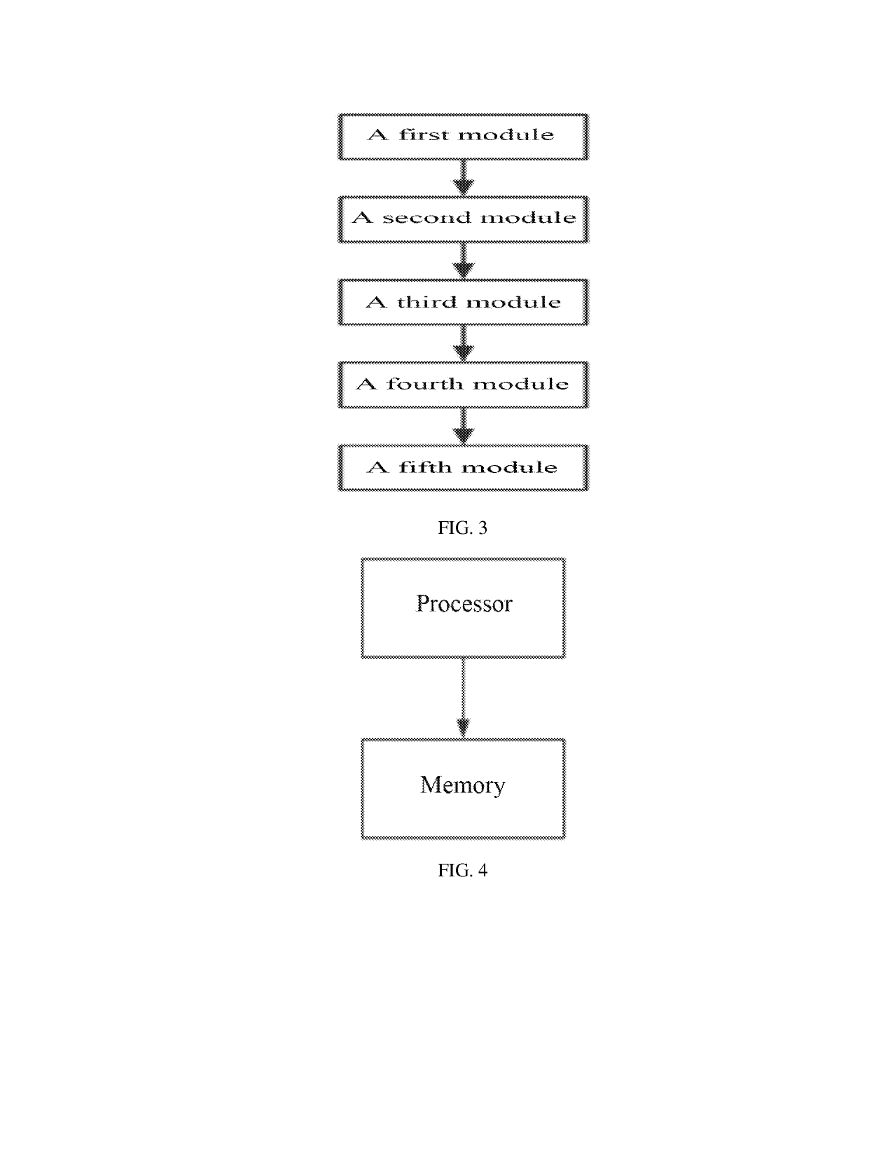

Secondly, referring to FIG. 3, the embodiments of the present disclosure provide an EMI value testing system for an LPDDR chip, which comprises:

a first module configured to obtain the first storage capacity of the LPDDR chip, where the first storage capacity represents the storage capacity corresponding to the first Rank;

a second module configured to obtain the second storage capacity of the LPDDR chip, wherein the second storage capacity represents the storage capacity corresponding to the second Rank;

a third module configured to compare the first storage capacity and the second storage capacity with a preset storage capacity respectively to obtain a first comparison result;

a fourth module configured to obtain a first EMI value and a second EMI value based on the first comparison result, a first storage table, and a second storage table, wherein the first storage table represents a relationship table between first parameter values and storage capacities, the second storage table represents a relationship table between second parameter values and storage capacities, the first EMI value represents the EMI value of the first Rank, and the second EMI value represents the EMI value of the second Rank;

a fifth module configured to determin the EMI value of the LPDDR chip based on the first EMI value and the second EMI value.

It can be seen that the content in the above method embodiments is applicable to this system embodiment. The specific functions achieved by this system embodiment are the same as those in the above method embodiments, and the beneficial effects achieved are also the same.

Thirdly, referring to FIG. 4, the embodiments of the present disclosure provide a memory testing device, which comprises:

at least one processor;

at least one memory for storing at least one program;

when the at least one program is executed by the at least one processor, it enables the at least one processor to implement the above method.

It can be seen that the content in the above method embodiments is applicable to this device embodiment. The specific functions achieved by this device embodiment are the same as those in the above method embodiments, and the beneficial effects achieved are also the same.

Fourthly, in addition, the embodiments of the present application also disclose a computer program product or computer program stored in a computer-readable storage medium. The processor of a computer device can read the computer program from the computer-readable storage medium, and the processor executes the computer program, enabling the computer device to implement the above method or system. Similarly, the content in the above method embodiments is applicable to this storage medium embodiment. The specific functions achieved by this storage medium embodiment are the same as those in the above method embodiments, and the beneficial effects achieved are also the same.

It can be understood that all or some of the steps and systems in the above-disclosed methods can be implemented as software, firmware, hardware, and appropriate combinations thereof. Some or all of the physical components can be implemented as software executed by a processor, such as a central processing unit, a digital information processor, or a microprocessor, or as hardware, or as integrated circuits, such as application-specific integrated circuits. Such software can be distributed on computer-readable media, which can comprise computer storage media (or non-transitory media) and communication media (or transitory media). As commonly known to those skilled in the art, the term computer storage media comprises volatile and non-volatile, removable and non-removable media implemented in any method or technology for storing information, such as computer-readable instructions, data structures, program modules, or other data. Computer storage media comprise, but are not limited to, RAM, ROM, EEPROM, flash memory, or other memory technologies, CD-ROM, digital versatile disks (DVDs), or other optical disk storage, magnetic cassettes, magnetic tapes, magnetic disk storage, or other magnetic storage devices, or any other media that can be used to store the desired information and can be accessed by a computer. In addition, as commonly known to those skilled in the art, communication media typically contain computer-readable instructions, data structures, program modules, or other data in modulated data information, such as carrier waves or other transmission mechanisms, and can comprise any information delivery media.

The above has provided a detailed description of the embodiments of the present disclosure with reference to the accompanying drawings. However, the present disclosure is not limited to the above embodiments. Within the scope of knowledge possessed by those skilled in the art, various changes can be made without departing from the purpose of the present disclosure.

1. An EMI value testing method for an LPDDR chip, comprising:
obtaining a first storage capacity of the LPDDR chip, wherein the first storage capacity represents storage capacity corresponding to a first Rank;

2. The method according to claim 1, wherein the obtaining the first EMI value and the second EMI value according to the first comparison result, the first storage table, and the second storage table comprises:
when the first comparison result indicates that the first storage capacity is less than or equal to the preset storage capacity, obtaining the first EMI value through the second storage table;

3. The method according to claim 2, wherein the method further comprises:
when the first comparison result indicates that both the first storage capacity and the second storage capacity are less than or equal to the preset storage capacity, comparing the first storage capacity and the second storage capacity to obtain a second comparison result;

4. The method according to claim 3, wherein obtaining the first EMI value or the second EMI value through the first storage table, and obtaining the first EMI value or the second EMI value through the second storage table comprises:

5. The method according to claim 1, wherein the determining the EMI value of the LPDDR chip according to the first EMI value and the second EMI value comprises:
obtaining a first weighting coefficient corresponding to the first EMI value and a second weighting coefficient corresponding to the second EMI value;

6. The method according to claim 4, wherein the obtaining the first parameter value from the first storage table according to the first storage capacity or the second storage capacity, and obtaining the second parameter value from the second storage table according to the first storage capacity or the second storage capacity comprises:

7. The method according to claim 1, wherein before the determining the EMI value of the LPDDR chip according to the first EMI value and the second EMI value, the method further comprises:
coefficient.

8. An EMI value testing system for an LPDDR chip, comprising:
a first module configured to obtain a first storage capacity of the LPDDR chip, wherein the first storage capacity represents storage capacity corresponding to a first Rank;

9. A memory testing device, comprising:
at least one processor;
at least one memory configured to store at least one program;
when the at least one program is executed by the at least one processor, the at least one processor execute the method according to claim 1.
